(19) United States
(12) Patent Application Publication
(10) Pub. No.: US 2023/0150889 A1
(43) Pub. Date: May 18, 2023

(54) AIR-PERMEABLE MEMBER, MEMBER FOR SEMICONDUCTOR MANUFACTURING DEVICE, PLUG, AND ADSORPTION MEMBER

(71) Applicant: KYOCERA CORPORATION, Kyoto-shi, Kyoto (JP)

(72) Inventor: Hiromasa MATSUFUJI, Higashiomi-shi, Shiga (JP)

(21) Appl. No.: 17/920,676

(22) PCT Filed: Apr. 22, 2021
(86) PCT No.: PCT/JP2021/016375

§ 371 Date: Oct. 21, 2022

(30) Foreign Application Priority Data
Apr. 27, 2020 (JP) 2020-078379

(51) Int. Cl. C04B 38/00; H01L 21/683; H01L 21/3065; C04B 35/48; C04B 35/505

(52) U.S. Cl. CPC C04B 38/007; H01L 21/6831; H01L 21/3065; C04B 35/48; C04B 35/505; C04B 38/0051; C04B 2235/3225; C04B 2235/3248; C04B 2235/762

(57) ABSTRACT

An air-permeable member of the present disclosure includes a porous ceramic having a columnar or plate shape. A root mean square slope RΔq in a roughness curve of an outer peripheral surface of the porous ceramic is greater than a root mean square slope RΔq in a roughness curve of a main surface of the porous ceramic.

### TECHNICAL FIELD

The present disclosure relates to an air-permeable member and a member for a semiconductor manufacturing device, such as a plug and an adsorption member, which includes the air-permeable member.

### BACKGROUND OF INVENTION

In the related art, in a semiconductor manufacturing device such as a plasma etching device, as disclosed in PTL 1, a plasma state is formed by applying a high-frequency voltage between a substrate such as a semiconductor wafer placed on a substrate support assembly and a shower plate (gas distribution plate) for introducing plasma generating gas and supplying the plasma generating gas toward the substrate, and a thin film is formed on a surface of the substrate or the thin film formed on the surface of the substrate is etched.

The substrate support assembly includes a through hole for supplying cooling gas such as helium in the thickness direction of the substrate support assembly, and an air-permeable plug made of a porous ceramic, such as AlO/SiO, AlO/MgO/SiO, SiC, SiN, or AlN/SiO, is inserted into the through hole.

PTLs 2 and 3 disclose a member for a semiconductor manufacturing device. The member includes an electrostatic chuck having a placement surface on which a wafer is placed, and a cooling plate located below the electrostatic chuck and having a gas supply hole for supplying cooling gas such as helium (He). The electrostatic chuck includes an internal space connected to the gas supply hole, and a gas discharge hole that is connected to the internal space and discharges the cooling gas having passed through the gas supply hole and the internal space. A circular plate-shaped air-permeable plug is mounted in the interior space to suppress discharge. An outer peripheral surface of an air-permeable plug disclosed in PTL 2 is fixed to the electrostatic chuck by an adhesive.

### CITATION LIST

### Patent Literature

PTL 1: JP 2018-162205 A
PTL 2: WO 2019/009028

### SUMMARY

An air-permeable member of the present disclosure includes a porous ceramic having a columnar or plate shape. A root mean square slope RΔq in a roughness curve of an outer peripheral surface of the porous ceramic is greater than a root mean square slope RΔq in a roughness curve of a main surface of the porous ceramic.

An air-permeable member of the present disclosure includes a porous ceramic having a columnar or plate shape. A root mean square slope RΔq in a roughness curve of an outer peripheral surface of the porous ceramic is from 0.2 to 0.8.

A member of the present disclosure for a semiconductor manufacturing device includes the above air-permeable member.

A plug of the present disclosure includes the above air-permeable member.

An adsorption member of the present disclosure includes the above air-permeable member.

### BRIEF DESCRIPTION OF THE DRAWINGS

FIG. 1 is a cross-sectional view illustrating a part of a plasma processing device including a plug that is an air-permeable member of the present disclosure.

FIG. 2 is an enlarged cross-sectional view of a substrate support assembly disposed inside the plasma processing device illustrated in FIG. 1.

FIG. 3A is a cross-sectional view schematically illustrating a member for a semiconductor manufacturing device, which includes a plug that is an air-permeable member of the present disclosure.

FIG. 3B is an enlarged cross-sectional view of portion A in FIG. 3A.

FIG. 4 is a schematic view illustrating an overview of a bevel etcher including an adsorption member that is an air-permeable member of the present disclosure.

FIG. 5 is an example illustrating an X-ray diffraction pattern of a porous ceramic of the present disclosure.

### DESCRIPTION OF EMBODIMENTS

An example of an air-permeable member of the present disclosure is described in detail below with reference to the drawings. However, in all drawings of the present specification, the same portions are assigned the same reference numerals, and the descriptions are omitted at appropriate time unless confusion is caused.

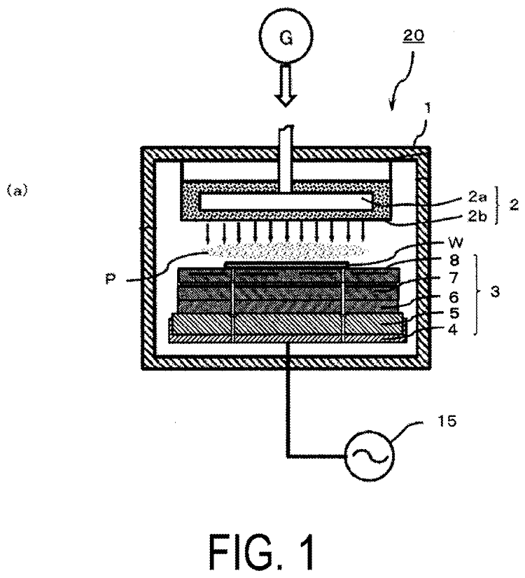

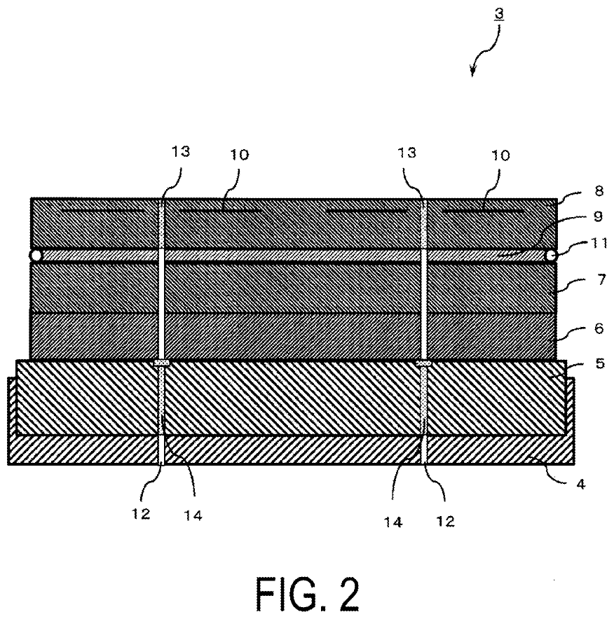

FIG. 1 is a cross-sectional view illustrating a part of a plasma processing device including a plug that is a member of the present disclosure for a semiconductor manufacturing device. FIG. 2 is an enlarged cross-sectional view of a substrate support assembly disposed inside the plasma processing device illustrated in FIG. 1.

A plasma processing device 20 illustrated in FIG. 1 is, for example, a plasma etching device, and is provided therein with a chamber 1 in which a to-be-treated member W such as a semiconductor wafer is disposed. In the chamber 1, a shower plate 2 is disposed on an upper side of the chamber 1 and a substrate support assembly 3 is disposed on a lower side of the chamber 1 with the substrate support assembly 3 facing the shower plate 2.

The shower plate 2 includes a diffusion portion 2a, which is an internal space for diffusing plasma generating gas G, and a gas supply portion 2b made of a porous ceramic and including a plurality of gas passages (pores) for supplying the plasma generating gas G into the chamber 1.

The plasma generating gas G discharged from the gas supply portion 2b in a shower form is turned into plasma by high-frequency power supplied from a high-frequency power supply 15, and forms a plasma space P.

Examples of the plasma generating gas G include fluorine-based gas such as SF₆, CF₄, CHF₃, ClF₃, NF₃, C₄F₈, and HF, and chlorine-based gas such as Cl₂, HCl, BCl₃, and CCl₄.

The substrate support assembly 3 is an electrostatic chuck including a mounting portion 4, an insulating portion 5, a support portion 6, a heat conductive portion 7, and an electrostatic adsorption portion 8. The electrostatic adsorption portion 8 is bonded to the heat conductive portion 7 via a bonding layer 9 made of, for example, a silicone adhesive, as illustrated in FIG. 2.

The electrostatic adsorption portion 8 holds the to-be-treated member W by an electrostatic adsorption force, and a plurality of clamp electrodes 10 are disposed inside the electrostatic adsorption unit 8. The clamp electrode 10 is electrically coupled to a high-frequency power source via a matching circuit for maintaining, in the chamber 1, the plasma P generated from the plasma generating gas G.

A coating film formed on the surface of the to-be-treated member W is etched by the ions or radicals contained in the plasma.

An O-ring 11 is mounted around the bonding layer 9 and protects the bonding layer 9. The insulating portion 5 is made of, for example, plastic and is electrically isolated from the mounting portion 4.

The substrate support assembly 3 includes through holes 12 that penetrate in a vertical direction. Plugs 13 and 14 are inserted into the through hole 12. That is, the plug 13 is installed in the through hole 12 in the electrostatic adsorption unit 8, and the plug 14 is installed in the through hole 12 in the insulating portion 5. The plug 13 is a columnar body having a straight body shape. The plug 14 is a columnar body including a columnar shaft portion and a flange portion provided at one end of the shaft portion and having a larger diameter than the shaft portion. The through hole 12 is a passage for supplying helium gas for cooling into the chamber 1.

The plugs 13 and 14 can capture particles floating in the plasma P when the plasma P used to clean the chamber 1 passes through the through hole 12, and suppress the entrance of such particles into the substrate support assembly 3. The plugs 13 and 14 can suppress secondary plasma generation in the through hole 12.

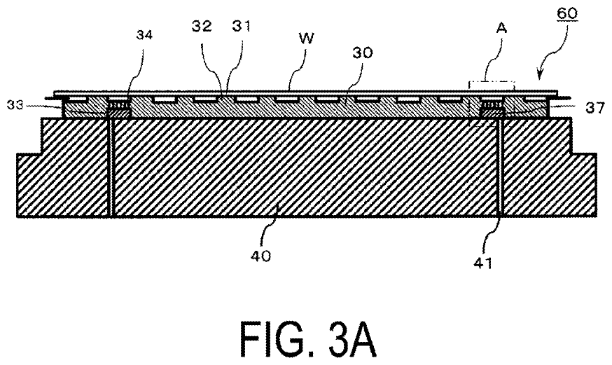

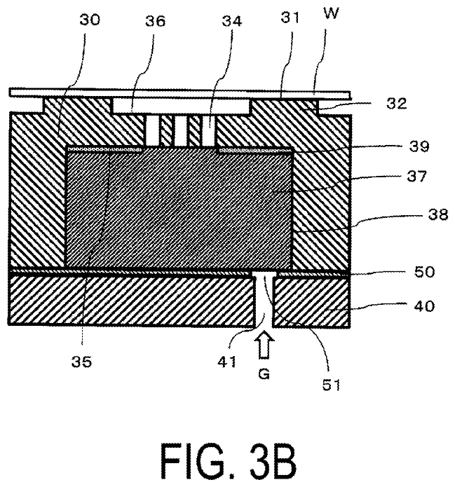

FIGS. 3A and 3B illustrate a schematic overview of a member for a semiconductor manufacturing device, which includes a plug that is an air-permeable member of the present disclosure. FIG. 3A is a cross-sectional view and FIG. 3B is an enlarged cross-sectional view of portion A.

A member 60 for a semiconductor manufacturing device includes an electrostatic chuck 30 having a placement surface 31 on which the to-be-treated member W such as a semiconductor wafer is placed, and a circular plate-shaped cooling member 40 that is located below the electrostatic chuck 30 and cools the to-be-treated member W. The electrostatic chuck 30 includes a plurality of convex portions 32 on the placement surface 31 side, and the placement surface 31 is a top surface of the convex portion 32.

The cooling member 40 is a circular plate-shaped member made of a metal having a high thermal conductivity, for example, aluminum, and includes a gas supply hole 41 for supplying cooling gas such as helium. The gas supply hole 41 penetrates in the thickness direction of the cooling member 40.

The electrostatic chuck 30 is a circular plate-shaped member made of a dense ceramic in which aluminum oxide, yttrium oxide, yttrium aluminum composite oxide (at least one of YAG, YAM or YAP), aluminum nitride, and the like are main components, and includes a plurality of internal spaces 33 and a plurality of gas discharge holes 34 communicating with the internal space 33. The internal space 33 communicates with the gas supply hole 41. The gas discharge hole 34 has a circular cross section, has a smaller diameter than the internal space 33, and penetrates a bottom surface 35 located on the internal space 33 side and a stepped surface 36 located below the placement surface 31.

The plurality of gas discharge holes 34 are provided for each internal space 33. The internal space 33 accommodates a plug 37 made of a circular plate-shaped porous ceramic.

Regarding the dimensions of the plug 37, for example, an outer diameter is from 4 mm to 8 mm and a thickness is from 0.8 mm to 1.5 mm.

The plug 37 is bonded to the bottom surface 35 via an insulating adhesive layer 39. The adhesive layer 39 includes, for example, a polyimide adhesive, an epoxy adhesive, a silicone sheet, and the like. In the member for a semiconductor manufacturing device illustrated in FIGS. 3A and 3B, the adhesive layer 39 is provided along the bottom surface 35, but an insulating adhesive layer may be provided along an inner peripheral surface 38 forming the internal space 33.

The plurality of gas discharge holes 34 are provided concentrically at the center position of the internal space 33 and around the center position, and the number of gas discharge holes 34 is, for example, from 5 to 9. The gas supply hole 41 is provided at a position shifted from the center position of the inner section 33 to an outer peripheral side.

The cooling member 40 and the electrostatic chuck 30 are bonded via an insulating adhesive layer 50. A portion of the adhesive layer 50, which is connected to the gas supply hole 41, is formed with a connection hole 51.

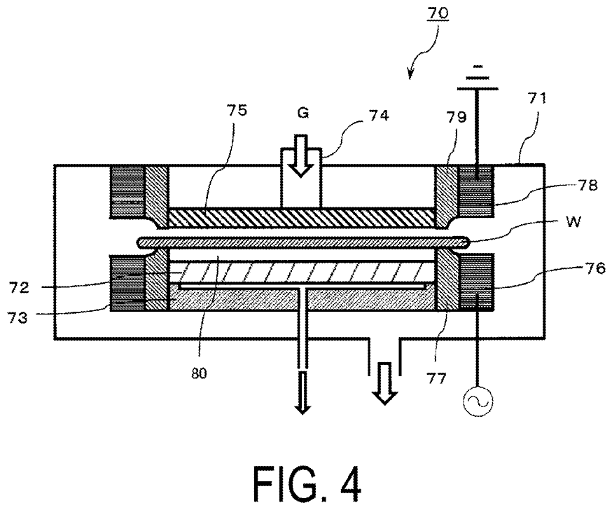

FIG. 4 is a schematic view illustrating an overview of a bevel etcher including an adsorption member that is an air-permeable member of the present disclosure. A bevel etcher 70 illustrated in FIG. 4 is a device for plasma cleaning, and includes a processing chamber 71 having an internal space, an adsorption member 72 such as a vacuum chuck for holding the to-be-treated member W, such as a semiconductor wafer, at a predetermined position inside the processing chamber 71, a support member 73 supporting the adsorption member 72, a shower plate 75 disposed above the adsorption member 72 and connected to a gas introduction pipe 74 for introducing the plasma generating gas G from a gas supply portion, a lower electrode 76 made of a conductive material, a lower support ring 77 located between the adsorption member 72 and the lower electrode 76, an upper electrode 78 made of a conductive material, and an upper ring 79 located between the shower plate 75 and the upper electrode 78.

Both the adsorption member 72 and the support member 73 have a circular plate shape, but the adsorption member 72 is made of a porous ceramic and the support member 73 is made of a dense ceramic.

Both the lower support ring 77 and the upper ring 79 are made of a ceramic in which aluminum oxide (Al₂O₃), aluminum nitride (AlN), silicon oxide (SiO₂), silicon carbide (SiC), silicon nitride (Si₃N₄), yttrium oxide (Y₂O₃), and the like are main components. A sealed region 80 is a space surrounded by the to-be-treated member W, the lower support ring 77, and the adsorption member 72. Gas pressure in the sealed region 80 is reduced by exhaust ventilation performed by a pump P so as to be lower than atmospheric pressure during operation.

The air-permeable member of the present disclosure, such as the plug and the adsorption member described above, is made of, for example, a columnar or circular plate-shaped porous ceramic including yttrium zirconate, aluminum oxide (Al₂O₃), yttrium aluminum composite oxide (at least one of YAG, YAM, or YAP), aluminum nitride (AlN), silicon oxide (SiO₂), silicon carbide (SiC), silicon nitride (Si₃N₄), and Yttrium oxide (Y₂O₃), and at least any one of them is as a main component.

In the air-permeable member of the present disclosure, a root mean square slope RΔq in a roughness curve of an outer peripheral surface of the porous ceramic is greater than a root mean square slope RΔq in a roughness curve of a main surface of the porous ceramic.

With such a configuration, in relation to the outer peripheral surface of the porous ceramic, when the air-permeable member such as the plug 13 or 14 is fixed to the electrostatic adsorption portion 8, the insulating portion 5, and the like by an adhesive, the adhesive enters deeply inward from the outer peripheral surface of the plug 13 or 14 along the slope of the uneven shape, and thus the air-permeable member can achieve high adhesive strength and maintain high reliability over a long period of time. A lower main surface, to which cooling gas such as helium is supplied, has smooth unevenness, particles floating in the chamber 1 are less likely to adhere, and thus an increase in ventilation resistance can be suppressed. An upper main surface from which the cooling gas is discharged also has smooth unevenness, the particles floating in the chamber 1 are less likely to deposit, and thus the cooling gas can be easily discharged over a long period of time.

In the air-permeable member of the present disclosure, a root mean square slope RΔq in a roughness curve of an outer peripheral surface of a porous ceramic is from 0.2 to 0.8.

When the root mean square slope RΔq in the roughness curve of the outer peripheral surface is 0.2 or more, the slope of the uneven shape of the outer peripheral surface becomes steep. In such a situation, fixing the air-permeable member such as the plug 13 or 14 to the electrostatic adsorption portion 8, the insulating portion 5, and the like by an adhesive makes the adhesive enter deeply inward from the outer peripheral surface of the plug 13 or 14 along the slope of the uneven shape, and thus, the air-permeable member can achieve high adhesive strength and maintain high reliability over a long period of time. On the other hand, when the root mean square slope RΔq in the roughness curve of the outer peripheral surface is 0.8 or less, mounting the air-permeable member such as the plug 13 or 14 on the electrostatic adsorption unit 8, the insulating portion 5, and the like decreases the number of particles detached from the air-permeable member and the number of particles floating in the space inside the chamber 1 even though the air-permeable member comes into such strong contact with the inner peripheral surfaces of these members so as to damage these members. Stress concentration occurring on the outer peripheral surface is also alleviated.

The root mean square slope RΔq in the roughness curve is the root mean square of a local slope dz/dx at a reference length l of the roughness curve, which is measured in accordance with JIS B 0601:2001, and is defined by the following equation.

$$Rdq = \sqrt{\frac{1}{ℓ} {\int }_{0}^{ℓ} ( \frac{d}{dx} {Z ( x )}^{2} dx} \qquad Math [ 1 ]$$

The higher the numerical value of the root mean square slope RΔq, the steeper the unevenness of the surface, and the lower the numerical value of the root mean square slope RΔq, the smoother the unevenness of the surface.

The root mean square slope RΔq in the roughness curve of at least one main surface of the porous ceramic may be from 0.2 to 0.8.

When the root mean square slope RΔq in the roughness curve of the main surface is 0.2 or more, the slope of the uneven shape of the main surface becomes steep. In such a situation, fixing the air-permeable member such as the plug to the electrostatic chuck 30 and the like by an adhesive makes the adhesive enter deeply inward from the main surface of the air-permeable member such as the plug 37 along the slope of the uneven shape, and thus the air-permeable member can achieve high adhesive strength and maintain high reliability over a long period of time. On the other hand, when the root mean square slope RΔq in the roughness curve of the main surface is 0.8 or less, mounting the air-permeable member such as the plug 37 on the electrostatic chuck 30 and the like decreases the number of particles detached from the air-permeable member and the number of particles floating in the space inside the chamber 1 even though the air-permeable member comes into such strong contact with the bottom surface 35 of the electrostatic chuck 30 so as to damage the bottom surface 35.

The root mean square slope RΔq can be measured using a shape analysis laser microscope (manufactured by Keyence Corporation, VK-X1100 or a successor model of VK-X1100) in accordance with JIS B 0601:2001. As the measurement conditions, first, a magnification is set to 240 times, a cutoff value λs is set to none, a cutoff value λc is set to 0.08 mm, a cutoff value λf is set to none, a measurement range per point from the main surface and the outer peripheral surface to be measured is set to, for example, 1420 μm×1070 μm, and line roughness is measured by drawing a line to be measured along the longitudinal direction of the central portion of each measurement range. The length to be measured is, for example, 1320 μm.

The air-permeable member of the present disclosure may be made of a porous ceramic including yttrium zirconate and yttrium oxide, and at least any one of the yttrium zirconate or the yttrium oxide is a main component.

With such a configuration, since the air-permeable member of the present disclosure includes the yttrium zirconate with high mechanical strength and the yttrium oxide with high corrosion resistance to plasma and at least any one of the yttrium zirconate or the yttrium oxide is a main component, the corrosion resistance to plasma increases while maintaining mechanical strength, and thus the air-permeable member can be used over a long period of time.

Specifically, the porous ceramic is classified into three types below.

(1) Porous ceramic including the yttrium zirconate as a main component and further including the yttrium oxide.
(2) Porous ceramic including the yttrium oxide as a main component and further including the yttrium zirconate.
(3) Porous ceramic including the yttrium zirconate and the yttrium oxide as main components.

The main constituent in the porous ceramic refers to a component including 50 mol % or more provided that the total of the components constituting the porous ceramic is 100 mol %. Each component constituting the porous ceramic can be identified using an X-ray diffractometer (XRD) using CuKα rays, and the molar ratio of each component can be calculated by Rietveld analysis using the XRD.

When the yttrium zirconate is a main component, the molar ratio of the yttrium oxide is 20 mol % or more. When the yttrium oxide is a main component, the molar ratio of the yttrium zirconate is 20 mol % or more.

When the molar ratio of each of the yttrium zirconate and the yttrium oxide is 50 mol %, both are main components.

The yttrium zirconate is represented by, for example, a compositional formula of YZrOₓ (3≤x≤3.5), YZr₂O₇, Y₂ZrO₅, Y₂Zr₂O₃, Zr_{0.92}Y_{0.08}O_{1.96}, and the like.

Both the yttrium zirconate and the yttrium oxide preferably have a cubic crystal structure. The crystal structure is determined by the X-ray diffractometer (XRD) using CuKα rays. Regarding the yttrium zirconate and the yttrium oxide, phase transformation does not degrade strength, and thus repeated use is available even in an environment where exposition to high temperature is repeated.

The porous ceramic may include at least any one of Si, Fe, Al, or a group 2 element in the periodic Table (hereinafter, the group 2 element in the periodic table is referred to as AE) as an oxide, in addition to the yttrium zirconate and the yttrium oxide, and Si may be 300 mass ppm or less in terms of SiO₂, Fe may be 50 mass ppm or less in terms of Fe₂O₃, Al may be 100 mass ppm or less in terms of Al₂O₃, and AE may be 350 mass ppm or less in terms of AEO.

The contents of these elements is preferably calculated by an inductively coupled plasma (ICP) emission spectrometer and converted to the above oxides.

The porous ceramic may include at least one metal element selected from the group consisting of iron, cobalt, and nickel, and the total content of the at least one metal element may be 0.1 mass % or less.

When the total content of these metal elements is 0.1 mass % or less, the porous ceramic can be made non-magnetic, so that the porous ceramic can be used, for example, as a member of a device such as an electron beam exposure device required to suppress the influence of magnetic properties. Furthermore, since the risk of discoloration occurring locally is suppressed, the commercial value is improved.

Particularly, the total content of these metal elements is preferably 0.001 mass % or less.

The porous ceramic includes at least one metal element selected from the group consisting of potassium, sodium, magnesium, and calcium, and the total content of the at least one metal element may be 0.001 mass % or less.

The oxide particles including at least one of potassium, sodium, magnesium, or calcium are likely to float by the plasma P, but when the total content of these metal elements is within the above range, this risk is suppressed. Furthermore, by setting these metals within the above range, the dielectric loss can also be reduced.

The content of each of these metal elements is preferably calculated using a glow discharge mass spectrometer (GDMS).

The porous ceramic in the present disclosure refers to a ceramic having a porosity of 10% by volume or more, and the porosity can be calculated by a mercury intrusion porosimetry.

The porosity inside the porous ceramic may be higher than the porosity of a surface layer portion.

When foreign matter floating in the internal space enters and is accumulated inside the porous ceramic, it may be difficult to remove this foreign matter, but when the porosity inside the porous ceramic is higher than the porosity of the surface layer portion, this risk can be reduced. When the porosity inside the porous ceramic is higher than the porosity of the surface layer portion, the porosity of the surface layer portion is decreased and the mechanical strength and fracture toughness of the surface layer portion are increased, so that the porous ceramic is easily mounted on the electrostatic adsorption unit 8, the insulating portion 5, and the like as the plug 13 or 14. Moreover, the porous ceramic is easily accommodated in the internal space 33 as the plug 37. For example, the porosity of the surface layer portion is ifrom 20% by volume to 40% by volume, and the porosity inside the porous ceramic is preferably from 1% by volume to 5% by volume compared to the porosity of the surface layer portion.

Here, the inside refers to a region within ±7% from a virtual center plane in the thickness direction of the porous ceramic and within 70% of the radius of the porous ceramic about the axis of the porous ceramic. The surface layer portion refers to a region within 35% of both main surfaces of the porous ceramic and within 15% of the radius from the outer peripheral surface of the porous ceramic as a starting point. A region excluding the inside of the porous ceramic and the surface layer portion is an intermediate portion.

The porous ceramic forming the plug 37 includes an annular convex portion (not illustrated) extending along a radial direction, and an outer peripheral side surface of the annular convex portion is preferably the outer peripheral surface of the porous ceramic. With such a configuration, when the porous ceramic is accommodated in the internal space 33 as the plug 37, a contact area with the inner peripheral surface 38 can be reduced compared to when there is no annular convex portion, and thus the risk of plucking out caused by contact is reduced. Furthermore, the annular convex portion preferably has an isosceles trapezoid shape in a cross-sectional view including the axis of the porous ceramic.

The thickness of the annular convex portion is, for example, from 80% to 85% of the thickness of the plug 37.

The porous ceramic may have a pore area occupation ratio from 20 area % to 45 area %. When the pore area occupation ratio is within this range, it is possible to suppress the thermal stress generated even when the temperature is repeatedly raised and lowered while suppressing a large decrease in mechanical strength.

The porous ceramic may have an average pore diameter from 1 μm to 6 μm. When the average pore diameter is within this range, it is possible to reduce the size of particles generated from around pores and inside the pores even when plasma generating gas passes through the porous ceramic, while suppressing a large decrease in mechanical strength.

The kurtosis of the pore diameter may be 2 or more.

When the kurtosis of the pore diameter is within this range, the number of pores having an abnormally large diameter is reduced, and thus particles generated from inside the pores can be relatively reduced.

The skewness of the pore diameter may be 0 or more.

When the skewness of the pore diameter is within this range, the number of pores having a small diameter is relatively large, and thus the generation ratio of large particles can be reduced.

The pore area occupation ratio and the average pore diameter are measured using image analysis software “Win ROOF (Ver.6.1.3)” (manufactured by Mitani Shoji Co., Ltd.) at a magnification of 100 times, with a measurement range of 3.1585×10⁵ μm² at one point on the surface and a pore diameter threshold of 0.8 μm. The pore area occupation ratio and the average pore diameter can be calculated by performing this measurement at four points.

The kurtosis of the pore diameter can be calculated using a function Kurt provided in Excel (registered trademark, Microsoft Corporation).

The skewness of the pore diameter can be calculated using a function Skew provided in Excel (registered trademark, Microsoft Corporation).

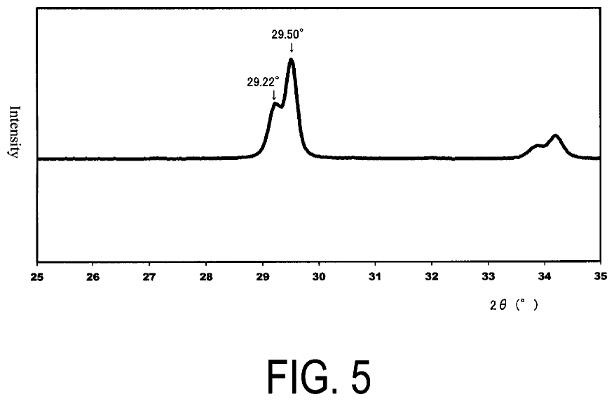

FIG. 5 is an example illustrating an X-ray diffraction pattern of the porous ceramic of the present disclosure.

The position of a diffraction peak I₁ of the (222) plane of the yttrium zirconate (YZrO₃) is a diffraction angle (2θ) 29.333° according to the card indicated by PDF (registered trademark) Number: 01-089-5593.

The position of a diffraction peak I₂ of the (222) plane of the yttrium oxide (Y₂O₃) is a diffraction angle (2θ) 29.211° according to the card indicated by PDF (registered trademark) Number: 01-071-0099. In the example illustrated in FIG. 5, the diffraction angle (2θ₁) of the diffraction peak I₁ of the (222) plane of the yttrium zirconate (YZrO₃) calculated by X-ray diffraction using CuKα rays is 29.22°, and a shift amount Δ₁ is 0.113° on a lower angle side. The diffraction angle (2θ₂) of the diffraction peak I₂ of the (222) plane of the yttrium oxide (Y₂O₃) is 29.50°, and a shift amount Δ₂ is 0.289° on a high angle side.

In the porous ceramic of the present disclosure, as illustrated in FIG. 5, the diffraction peak I₁ may be shifted to the low angle side and the diffraction peak I₂ may be shifted to the high angle side. When the diffraction peak I₁ is shifted to the low angle side, a lattice spacing of crystal grains increases and tensile stress remains in a crystal lattice. On the other hand, when the diffraction peak I₂ is shifted to the high angle side, the lattice spacing of the crystal grains decreases and compressive stress remains in the crystal lattice. When the tensile stress and the compressive stress remain in this way, the tensile stress and the compressive stress act to cancel each other, and thus plucking out is less likely to occur.

In the porous ceramic, both the absolute values of the shift amount Δ₁ of the diffraction peak I₁ and the shift amount Δ₂ of the diffraction peak I₂ may be 0.5° or less. When the shift amount Δ₁ and the shift amount Δ₂ are within this range, the strain accumulated in the crystal lattice decreases, and thus the porous ceramic can be used over a long period of time.

An example of a method of manufacturing the air-permeable member of the present disclosure is described.

Yttrium oxide powder and zirconium oxide powder are prepared. After the yttrium oxide and the zirconium oxide are blended so that the molar ratio is from 55:45 to 65:35, they are sequentially wet-mixed and granulated to produce granules made of the yttrium oxide and the zirconium oxide.

In order to produce an air-permeable member in which the diffraction peak I₁ of the (222) plane of yttrium zirconate (YZrO₃) is shifted to the low angle side and the diffraction peak I₂ of the (222) plane of yttrium oxide (Y₂O₃) is shifted to the high angle side, it is only required that an average particle size D₅₀ of the wet-mixed powder be from 0.8 μm to 0.9 μm.

In order to produce an air-permeable member in which the absolute values of the shift amount Δ₁ of the diffraction peak I₁ and the shift amount Δ₂ of the diffraction peak I₂ are 0.5° or less, it is only required that the average particle size D₅₀ of the wet-mixed powder be from 0.82 μm to 0.88 μm.

In order to produce a porous ceramic including at least one metal element selected from the group consisting of iron, cobalt, and nickel and having the total content of the at least one metal element of 0.1 mass % or less, it is only required that a deironizer be used to perform a deironization process with a magnetic flux density of 1 tesla and a processing time of 60 minutes or longer, for example.

The granules are filled into a molding die and molded into a predetermined shape (columnar or circular plate shape) by dry pressing, cold isostatic pressing, or the like. The molding pressure is preferably from 78 Mpa to 118 Mpa, for example.

In order to produce an air-permeable member in which a root mean square slope RΔq in a roughness curve of an outer peripheral surface of the porous ceramic is from 0.2 to 0.8, a root mean square slope RΔq in a roughness curve of an inner peripheral surface of a die constituting a molding die is set in a range from 0.22 to 0.88 in consideration of shrinkage. The inner peripheral surface of the die is transferred to the outer peripheral surface of the molded article.

In order to produce an air-permeable member in which a root mean square slope RΔq in a roughness curve of at least one main surface of the porous ceramic is from 0.2 to 0.8, it is only required that a root mean square slope RΔq in a roughness curve of a pressing surface of at least one of an upper punch or a lower punch constituting a molding die be set in a range from 0.22 to 0.88 in consideration of shrinkage. The pressing surface is transferred to the main surface of the molded article.

The molded article produced by molding is fired in an air atmosphere with a holding temperature of 1200° C. to 1600° C. and a holding time of 1 hour to 5 hours. As described above, the air-permeable member of the present disclosure can be produced by the aforementioned manufacturing method.

In order to produce an air-permeable member having a pore area occupation ratio of 20 area % to 45 area %, it is only required that a holding temperature be set in a range from 1250° C. to 1550° C.

In order to produce an air-permeable member having an average pore size of 1 μm to 6 μm, it is only required that molding pressure be set in a range from 88 Mpa to 108 Mpa and a holding temperature be set in a range from 1250° C. to 1550° C., for example.

The air-permeable member of the present disclosure produced by the aforementioned manufacturing method can be used over a long period of time because few particles are detached and the reliability of adhesion can be maintained even though the air-permeable member is inserted into a through hole or an internal space.

Once the air-permeable member of the present disclosure is used, high adhesive strength can be achieved and high reliability can be maintained over a long period of time. Moreover, since the number of particles detached from the air-permeable member of the present disclosure is reduced, the number of particles floating in a space within a chamber is reduced, and thus reliability can be maintained over a long period of time after the air-permeable member is fixed to an adsorption portion, an insulating portion, or the like.

Although an air-permeable member according to the embodiment of the present disclosure has been described above, the present disclosure is not limited to the above embodiment, and various changes and improvements can be made within the scope of the present disclosure. For example, the above porous ceramic is not limited to a columnar shape or a circular plate shape, and may be a prismatic or polygonal plate shape, and the air-permeable member of the present disclosure can be used not only as a member for a semiconductor manufacturing device, but also as a catalyst carrier.

### REFERENCE SIGNS

1 Chamber
2 Shower plate
3 Substrate support assembly
4 Mounting portion
5 Insulating portion
6 Support portion
9 Bonding layer
10 Clamp electrode
11 O ring
12 Through hole
13 Plug
14 Plug
15 High-frequency power supply
20 Plasma processing device
30 Electrostatic chuck
31 Placement surface
32 Convex portion
33 Internal space
34 Gas discharge hole
35 Bottom surface
36 Stepped surface
37 Plug
40 Cooling member
41 Gas supply hole
50 Adhesive layer
51 Connection hole
60 Member for semiconductor manufacturing device
70 Bevel etcher
71 Processing chamber
72 Adsorption member
73 Support member
74 Gas introduction pipe
75 Shower plate
76 Lower electrode
77 Lower support ring
78 Upper electrode
79 Upper ring

1. An air-permeable member comprising:
a porous ceramic having a columnar or plate shape, wherein
a root mean square slope RΔq in a roughness curve of an outer peripheral surface of the porous ceramic is greater than a root mean square slope RΔq in a roughness curve of a main surface of the porous ceramic.

2. An air-permeable member comprising:
a porous ceramic having a columnar or plate shape, wherein
a root mean square slope RΔq in a roughness curve of an outer peripheral surface of the porous ceramic is from 0.2 to 0.8.

3. The air-permeable member according to claim 2, wherein a root mean square slope RΔq in a roughness curve of at least one main surface of the porous ceramic is from 0.2 to 0.8, provided that the root mean square slope RΔq of the at least one main surface is smaller than the root mean square slope RΔq of the outer peripheral surface.

4. The air-permeable member according to claim 1, wherein the porous ceramic includes yttrium zirconate and yttrium oxide, and at least any one of the yttrium zirconate or the yttrium oxide is a main component.

5. The air-permeable member according to claim 4, wherein the porous ceramic includes the yttrium zirconate as a main component and further includes the yttrium oxide.

6. The air-permeable member according to claim 4, wherein the porous ceramic includes the yttrium oxide as a main component and further includes the yttrium zirconate.

7. The air-permeable member according to claim 4, wherein the porous ceramic includes the yttrium zirconate and the yttrium oxide as main components.

8. The air-permeable member according to claim 4, wherein both the yttrium zirconate and the yttrium oxide have a cubic crystal structure.

9. The air-permeable member according to claim 4, wherein a diffraction peak I1 of a (222) plane of yttrium zirconate (YZrO₃) is shifted to a low angle side and a diffraction peak I2 of a (222) plane of yttrium oxide (Y₂O₃) is shifted to a high angle side, the diffraction peak I1 and the diffraction peak I2 being determined by X-ray diffraction.

10. The air-permeable member according to claim 9, wherein absolute values of a shift amount Δ1 of the diffraction peak I1 and a shift amount Δ2 of the diffraction peak I2 are each 0.5° or less.

11. The air-permeable member according to claim 1, wherein a porosity inside the porous ceramic is higher than a porosity of a surface layer portion of the porous ceramic.

12. The air-permeable member according to claim 1, wherein the porous ceramic includes an annular convex portion extending along a radial direction, and an outer peripheral side surface of the annular convex portion is the outer peripheral surface of the porous ceramic.

13. The air-permeable member according to claim 1, wherein the porous ceramic has a pore area occupation ratio from 20 area % to 45 area %.

14. The air-permeable member according to claim 1, wherein the porous ceramic has an average pore diameter from 1 μm to 6 μm.

15. The air-permeable member according to claim 1, wherein the porous ceramic further includes at least one metal element selected from a group consisting of iron, cobalt, and nickel, wherein
a total content of the metal element is 0.1 mass % or less.

16. The air-permeable member according to claim 1, wherein the porous ceramic further includes at least one metal element selected from a group consisting of potassium, sodium, magnesium, and calcium, wherein
a total content of the metal element is 0.001 mass % or less.

17. A member for a semiconductor manufacturing device comprising the air-permeable member according to claim 1.

18. A plug comprising the air-permeable member according to claim 1.

19. An adsorption member comprising the air-permeable member according to claim 1.
